(19) United States
(12) Patent Application Publication
(10) Pub. No.: US 2010/0194246 A1
(43) Pub. Date: Aug. 5, 2010

(54) Thin-Film Bulk Acoustic Resonators Having Reduced Susceptibility to Process-Induced Material Thickness Variations

(75) Inventors: Ye Wang, Cupertino, CA (US); Harmeet Bhugra, San Jose, CA (US)

Correspondence Address: MYERS BIGEL SIBLEY & SAJOVEC, PO BOX 37428, RALEIGH, NC, 27627, US

(73) Assignee: Integrated Device Technology, Inc.

(21) Appl. No.: 12/363,142

(22) Filed: Jan. 30, 2009

(51) Int. Cl. H01L 41/047

(52) U.S. Cl. 310/365

(57) ABSTRACT

Thin-film bulk acoustic resonators include a resonator body (e.g., silicon body), a bottom electrode on the resonator body and a piezoelectric layer on the bottom electrode. At least one top electrode is also provided on the piezoelectric layer. In order to inhibit process-induced variations in material layer thicknesses from significantly affecting a desired resonant frequency of the resonator, the top and bottom electrodes are fabricated to have a combined thickness that is proportional to a target thickness of the piezoelectric layer extending between the top and bottom electrodes.

### FIELD OF THE INVENTION

The present invention relates to integrated circuit devices and, more particularly, to micro-electromechanical devices and methods of forming same.

### BACKGROUND OF THE INVENTION

Micro-electromechanical (MEMs) resonators that are operated in a lateral bulk extension mode may have several critical parameters that can influence resonator operating frequency. Some of these critical parameters can be highlighted by modeling performance of a resonator using a simplified bulk acoustic wave equation: f=v/(2L), where f is a resonant frequency, v is an acoustic velocity of the resonator material and L is the lateral dimension of the resonator along an axis of vibration. For a bulk acoustic resonator containing a composite stack of layers, the acoustic velocity is a function of the Young's modulus, density and thickness of each of the multiple layers. Accordingly, because the thicknesses of the multiple layers may vary during deposition processes, variations in resonant frequency may be present between otherwise equivalent devices formed across a wafer(s). In particular, variations in thicknesses of 1-2% across a wafer may cause significant deviations in frequency on the order of several thousands of parts-per-million (ppm).

### SUMMARY OF THE INVENTION

Thin-film bulk acoustic resonators according to embodiments of the present invention may have reduced susceptibility to process-induced variations in resonant frequency when material thicknesses of at least two layers within the resonators are within predetermined ranges relative to each other. According to some of these embodiments of the invention, a thin-film bulk acoustic resonator includes a resonator body (e.g., silicon body), a bottom electrode on the resonator body and a piezoelectric layer on the bottom electrode. At least one top electrode is also provided on the piezoelectric layer. In order to inhibit process-induced variations in material layer thicknesses from significantly affecting a desired resonant frequency of the resonator, the top and bottom electrodes are fabricated to have a combined thickness that is proportional to a desired thickness of the piezoelectric layer extending between the top and bottom electrodes.

In particular, according to some embodiments of the present invention, the combined thickness “t₃” of the top and bottom electrodes are preferably formed to be within the following range:

$${t }_{2} [ \frac{{E}_{2} {ρ}_{1} - {E}_{1} {ρ}_{2}}{{E}_{1} {ρ}_{3} - {E}_{3} {ρ}_{1}} ] \leq {t}_{3} \leq 2 {t}_{2} [ \frac{{E}_{2} {ρ}_{1} - {E}_{1} {ρ}_{2}}{{E}_{1} {ρ}_{3} - {E}_{3} {ρ}_{1}} ] ,$$

where “t₂” is the thickness of the piezoelectric layer; E₁, E₂ and E₃ are the Young's modulus of the resonator body, the piezoelectric layer and the bottom and top electrodes, respectively; and p₁, p₂ and p₃ are the densities of the resonator body, the piezoelectric layer and the bottom and top electrodes, respectively. By maintaining the combined thickness within the designated range, an effective acoustic velocity and resonant frequency of the resonator may be maintained at relatively uniform values even when process-induced variations in thickness are present in the resonator body. Moreover, maintaining the combined thickness t₃ of the top and bottom electrodes within the following narrower range may yield a resonant frequency of the resonator that is more immune to process-induced thickness variations:

$$1.6 {t}_{2} [ \frac{{E}_{2} {ρ}_{1} - {E}_{1} {ρ}_{2}}{{E}_{1} {ρ}_{3} - {E}_{3} {ρ}_{1}} ] \leq {t}_{3} \leq 2 {t}_{2} [ \frac{{E}_{2} {ρ}_{1} - {E}_{1} {ρ}_{2}}{{E}_{1} {ρ}_{3} - {E}_{3} {ρ}_{1}} ] .$$

According to still further embodiments of the invention, the bottom and top electrodes of the resonator are formed of a metal selected from a group consisting of molybdenum (Mo) and aluminum (Al), however, other metals and electrically conductive materials may also be used. In addition, the piezoelectric layer may include aluminum nitride (AlN) or other suitable piezoelectric materials.

Additional embodiments of the invention may also include an electrically insulating compensation layer on the resonator body. The addition of this compensation layer, which may be a thermal compensation layer, such as silicon dioxide, may alter the desired ratio of “t₃” to “t₂”. In addition, an adhesion layer may also be provided, which extends between the compensation layer and the bottom electrode. The adhesion layer may be formed of the same material as the piezoelectric layer and the thickness “t₂” may be treated as a combined thickness of the piezoelectric layer and the adhesion layer.

A thin-film bulk acoustic resonator according to still further embodiments of the invention may include a resonator body, a compensation layer on top or bottom of the resonator body, and a bottom electrode on the resonator body. A piezoelectric layer is also provided on the bottom electrode and a top electrode is provided on the piezoelectric layer. The addition of a compensation layer, which may operate as a temperature compensation layer, may cause a change in the preferred relative thicknesses of the piezoelectric and electrode layers. In particular, the top and bottom electrodes may have a combined thickness of t₃ within the following range:

$$[ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ] \leq {t}_{3} \leq 2 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ]$$

where t₂ and t₄ are the thicknesses of the piezoelectric layer and the compensation layer, respectively; E₁, E₂, E₃ and E₄ are the Young's modulus of the resonator body, the piezoelectric layer, the bottom and top electrodes and the compensation layer, respectively; and p₁, p₂, p₃ and p₄ are the densities of the resonator body, the piezoelectric layer, the bottom and top electrodes and the compensation layer, respectively.

According to additional embodiments of the invention, the top and bottom electrodes may have a combined thickness of t₃ within the following narrower range in order to achieve a greater degree of immunity from process-induced thickness variations:

$$1.6 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ] \leq {t}_{3} \leq 2 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ]$$

Still further embodiments of the present invention include a thin-film bulk acoustic resonator having a resonator body and a bottom electrode of molybdenum (Mo) on the resonator body. A piezoelectric layer is provided on the bottom electrode and at least one top electrode of molybdenum is provided on the piezoelectric layer. The top and bottom electrodes have a combined thickness in a range from greater than about 0.12 to about 0.24 times a thickness of the piezoelectric layer. Alternatively, the top and bottom electrodes may be formed of aluminum and the top and bottom aluminum electrodes may have a combined thickness in a range from greater than about 0.46 to about 0.93 a thickness of the piezoelectric layer.

### BRIEF DESCRIPTION OF THE DRAWINGS

FIG. 1 is a perspective view of a portion of a thin-film bulk acoustic resonator according to an embodiment of the present invention.

FIG. 2A is a graph illustrating frequency variation (ppm) versus silicon resonator body thickness, for thin-film bulk acoustic resonators having aluminum nitride (AlN) piezoelectric layers of varying thickness ranging from 0.5 to 1.0 microns and molybdenum (Mo) electrodes with a combined thickness of 0.1 microns.

FIG. 2B is a graph illustrating frequency variation (ppm) versus silicon resonator body thickness, for thin-film bulk acoustic resonators having aluminum nitride (AlN) piezoelectric layers of varying thickness ranging from 0.5 to 1.0 microns and aluminum (Al) electrodes with a combined thickness of 0.4 microns.

FIG. 2C is a graph illustrating frequency variation (ppm) versus silicon resonator body thickness, for: (i) thin-film bulk acoustic resonators having aluminum nitride (AlN) piezoelectric layers of varying thickness ranging from 0.5 to 1.0 microns and molybdenum (Mo) electrodes with a combined thickness of 0.1 microns; and (ii) thin-film bulk acoustic resonators having aluminum nitride (AlN) piezoelectric layers of varying thickness ranging from 0.5 to 1.0 microns, molybdenum (Mo) electrodes with a combined thickness of 0.1 microns and a 1.0 micron thick silicon dioxide compensation layer.

FIG. 3A is a graph illustrating frequency variation (ppm) versus silicon resonator body thickness, for thin-film bulk acoustic resonators having aluminum nitride (AlN) piezoelectric layers of varying thickness ranging from 2.0 to 2.5 microns, aluminum (Al) electrodes with a combined thickness of 0.4 microns and a 1.0 micron thick silicon dioxide compensation layer.

FIG. 3B is a graph illustrating frequency variation (ppm) versus silicon resonator body thickness, for thin-film bulk acoustic resonators having aluminum nitride (AlN) piezoelectric layers of varying thickness ranging from 2.0 to 2.5 microns, molybdenum (Mo) electrodes with a combined thickness of 0.1 microns and a 1.0 micron thick silicon dioxide compensation layer.

### DESCRIPTION OF PREFERRED EMBODIMENTS

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

It will be understood that when an element or layer is referred to as being “on,” “connected to” or “coupled to” another element or layer (and variants thereof), it can be directly on, connected or coupled to the other element or layer or intervening elements or layers may be present. In contrast, when an element is referred to as being “directly on,” “directly connected to” or “directly coupled to” another element or layer (and variants thereof), there are no intervening elements or layers present. Like reference numerals refer to like elements throughout. As used herein, the term “and/or” includes any and all combinations of one or more of the associated listed items and may be abbreviated as “/”.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprising”, “including”, “having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components.

Embodiments of the present invention are described herein with reference to cross-section and perspective illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a sharp angle may be somewhat rounded due to manufacturing techniques/tolerances.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

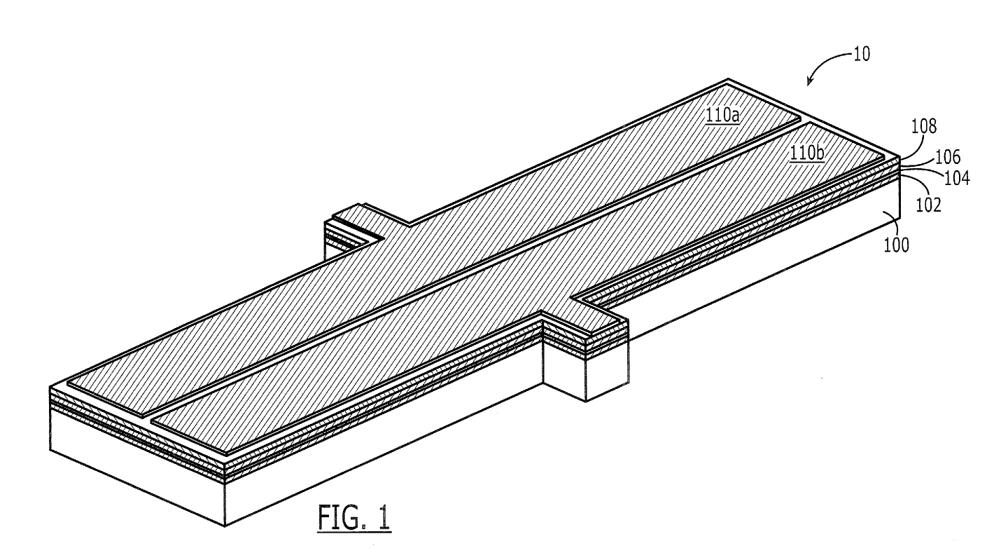

FIG. 1 is a perspective view of a portion of a thin-film bulk acoustic resonator 10 according to an embodiment of the present invention. The illustrated portion of the resonator 10 includes a composite of layers that may be collectively anchored on opposite sides to a surrounding substrate (not shown). This surrounding substrate may include a recess therein that extends underneath the illustrated portion of the resonator 10. Thus, the illustrated portion of the resonator 10 may be anchored to the surrounding substrate in a manner similar to the anchoring techniques illustrated and described in U.S. application Ser. No. 12/233,395, filed Sep. 18, 2008, entitled “Single-Resonator Dual-Frequency Lateral-Extension Mode Piezoelectric Oscillators, and Operating Methods Thereof,” and US 2008/0246559 to Ayazi et al., entitled “Lithographically-Defined Multi-Standard Multi-Frequency High-Q Tunable Micromechanical Resonators,” the disclosures of which are hereby incorporated herein by reference.

The composite of layers within the resonator 10 include a resonator body 100, a compensation layer 102, which may be optional, an adhesion layer 104, which may be optional, a bottom electrode 106, a piezoelectric layer 108 and an at least one top electrode (110a, 110b). As will be understood by those skilled in the art, the resonator body 100 may be formed as a semiconductor body, such as a single crystal silicon (Si) body, a quartz body or a body of other suitable material having low acoustic loss. The compensation layer 102 may be formed as an electrically insulating dielectric layer, such as a silicon dioxide layer, a silicon nitride layer or another electrically insulating layer having a sufficiently positive temperature coefficient of elasticity.

The compensation layer 102 is illustrated as being formed directly on an upper surface of the resonator body 100, however, the compensation layer 102 may also be formed on an opposing bottom surface of the resonator body 100, according to alternative embodiments of the invention. The compensation layer 102 may operate to provide thermal compensation to the resonator 10.

The adhesion layer 104 is illustrated as being formed directly on an upper surface of the compensation layer 102. This adhesion layer 104, which may be formed of the same material as the piezoelectric layer 108, is provided between the compensation layer 102 (and/or resonator body 100) and the bottom electrode 106, which may be electrically biased at a fixed bias potential (e.g., reference voltage). This bottom electrode 106 may be formed as a metal layer, such as a molybdenum (Mo) or aluminum (Al) layer, for example. Other metals (e.g., Au, Ni) may also be used for the bottom electrode 106.

The resonator 10 further includes a piezoelectric layer 108 on the bottom electrode 106. This piezoelectric layer 108 may be formed of a piezoelectric material, such as aluminum nitride (AlN), zinc oxide (ZnO) or PZT, for example. The at least one top electrode is illustrated as including a first top electrode 110a, which may operate as an input electrode of the resonator 10, and a second top electrode 110b, which may operate as an output electrode of the resonator 10. The at least one top electrode and bottom electrode are preferably formed of the same materials.

As will now be described, by fixing the thicknesses of the resonator body 100, a relationship can be established between the combined thicknesses of the piezoelectric layer 108 and the adhesion layer 104, if any, and the combined thicknesses of the bottom electrode 106 and top electrodes 110a, 110b. This relationship may be used to reduce a susceptibility of the resonator 10 to process-induced variations in resonant frequency when the material thickness of the resonator body 100 deviates from its target thickness for a given resonator design. This reduction in susceptibility of the resonator 10 to process-induced variations in resonant frequency may be understood by modeling the resonant frequency of the resonator 10 as a function of the thickness (tᵢ), Young's modulus (Eᵢ) and density (pᵢ) of the layers illustrated by FIG. 1, for the case where no compensation layer is present. This modeling can be illustrated by the following bulk acoustic wave equation, which applies to a three-material resonator containing a resonator body (1), a piezoelectric layer (2) and an electrode layer (3):

$$f = \frac{n}{2 L} \sqrt{\frac{{E}_{1} {t}_{1} + {E}_{2} {t}_{2} + {E}_{3} {t}_{3}}{{ρ}_{1} {t}_{1} + {ρ}_{2} {t}_{2} + {ρ}_{3} {t}_{3}}} \qquad ( 1 )$$

where “n” is the order of mode and L is the frequency defining dimension. This equation can be reduced to a bulk acoustic wave equation for a simplified body-only (e.g., Si only) resonator, which is typically characterized as a resonator having a very low susceptibility to process-induced variations in resonant frequency when body thickness variations occur during fabrication. In particular, the reduction in the acoustic wave equation for a three-material resonator can be achieved by satisfying the following relationship between the combined thicknesses of the piezoelectric layer 108 and the adhesion layer 104, if any, and the combined thicknesses of the bottom electrode 106 and the top electrodes 110a, 110b:

$$1 = \sqrt{\frac{{t}_{1} + \frac{{E}_{2}}{{E}_{1}} {t}_{2} + \frac{{E}_{3}}{{E}_{1}} {t}_{3}}{{t}_{1} + \frac{{ρ}_{2}}{{ρ}_{1}} {t}_{2} + \frac{{ρ}_{3}}{{ρ}_{1}} {t}_{3}}} \qquad ( 2 )$$

This relationship can be further simplified to eliminate the thickness of the resonator body therefrom and establish a preferred ratio in thicknesses between the combined electrode layers (t₃) and the piezoelectric layer (t₂) (or piezoelectric layer and adhesion layer):

$$\frac{{t}_{3}}{{t}_{2}} = \frac{{E}_{2} {ρ}_{1} - {E}_{1} {ρ}_{2}}{{E}_{1} {ρ}_{3} - {E}_{3} {ρ}_{1}} \qquad ( 3 )$$

This simplified equation can be further reduced to a ratio of t₃/t₂ of about 0.12 based on the material characteristics of Si, AlN and Mo illustrated by TABLE 1, or about 0.46 based on the material characteristics of Si, AlN and Al.

TABLE 1

| | YOUNG'S | DENSITY |
|---|---|---|
| MATERIAL | MODULUS (GPa) | (Kg/m³) |
| Si (1) | 169 | 2330 |
| AlN (2) | 295 | 3260 |
| Mo (3) | 220 | 9700 |
| Al (3′) | 70 | 2700 |
| SiO₂ (4) | 73 | 2200 |

According to still further embodiments of the present invention, the above-described modeling can be extended to a four-material resonator containing a resonator body (1), a piezoelectric layer (2), an electrode layer (3) and a compensation layer (4). In particular, a reduction in the acoustic wave equation for a four-material resonator can be achieved by satisfying the following relationship between the combined thicknesses of the piezoelectric layer 108 and adhesion layer 104, if any, the combined thicknesses of the bottom electrode 106 and top electrodes 110a, 110b and the thickness of the compensation layer:

$$1 = \sqrt{\frac{{t}_{1} + \frac{{E}_{2}}{{E}_{1}} {t}_{2} + \frac{{E}_{3}}{{E}_{1}} {t}_{3} + \frac{{E}_{4}}{{E}_{1}} {t}_{4}}{{t}_{1} + \frac{{ρ}_{2}}{{ρ}_{1}} {t}_{2} + \frac{{ρ}_{3}}{{ρ}_{1}} {t}_{3} \frac{{ρ}_{4}}{{ρ}_{1}} {t}_{4}}} \qquad ( 4 )$$

This equation can be further simplified to eliminate the thickness of the resonator body therefrom:

$$\frac{{E}_{2}}{{E}_{1}} {t}_{2} + \frac{{E}_{3}}{{E}_{1}} {t}_{3} + \frac{{E}_{4}}{{E}_{1}} {t}_{4} = \frac{{ρ}_{2}}{{ρ}_{1}} {t}_{2} + \frac{{ρ}_{3}}{{ρ}_{1}} {t}_{3} + \frac{{ρ}_{4}}{{ρ}_{1}} {t}_{4} \qquad ( 5 )$$

Moreover, by establishing a material and thickness of the compensation layer (4), the values of E₄, p₄ and t₄ become known, the desired value of t₃ can be computed once the target value of t₂ has been established (or vice versa).

Although not wishing to be bound by any theory, finite element simulation methods can be used to demonstrate the accuracy of the above analytical approach to reducing process-induced variations in resonant frequency for those cases where the resonator's frequency defining dimension (i.e., body length) is substantially larger than the width of the resonator body. However, for those cases where the resonator's frequency defining dimension is much smaller than the width of the resonator body, the analytical predictions can be off by a factor of about two when compared to the finite element simulation results. Accordingly, by combining the analytical predictions with finite element results, process-induced variations in resonant frequency can be reduced in a three-material resonator when the combined thickness “t₃” of the top and bottom electrodes is formed to be within the following range:

$${t}_{2} [ \frac{{E}_{2} {ρ}_{1} - {E}_{1} {ρ}_{2}}{{E}_{1} {ρ}_{3} - {E}_{3} {ρ}_{1}} ] \leq {t}_{3} \leq 2 {t}_{2} [ \frac{{E}_{2} {ρ}_{1} - {E}_{1} {ρ}_{2}}{{E}_{1} {ρ}_{3} - {E}_{3} {ρ}_{1}} ] \qquad ( 6 )$$

where “t₂” is the thickness of the piezoelectric layer; E₁, E₂ and E₃ are the Young's modulus of the resonator body, the piezoelectric layer and the bottom and top electrodes, respectively; and p₁, p₂ and p₃ are the densities of the resonator body, the piezoelectric layer and the bottom and top electrodes, respectively.

Similarly, by combining the analytical predictions with finite element results, process-induced variations in resonant frequency can be reduced in a four-material resonator when the combined thickness “t₃” of the top and bottom electrodes is formed to be within the following range:

$$[ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ] \leq {t}_{3} \leq 2 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ] \qquad ( 7 )$$

where t₂ and t₄ are the thicknesses of the piezoelectric layer and the compensation layer, respectively; E₁, E₂, E₃ and E₄ are the Young's modulus of the resonator body, the piezoelectric layer, the bottom and top electrodes and the compensation layer, respectively; and p₁, p₂, p₃ and p₄ are the densities of the resonator body, the piezoelectric layer, the bottom and top electrodes and the compensation layer, respectively. Finite element simulation results further demonstrate that a preferred scaling factor of about 1.6 can be added to the left sides of equations (6) and (7) for those cases where the resonator's frequency defining dimension (i.e., body length) is not substantially larger than the width of the resonator body.

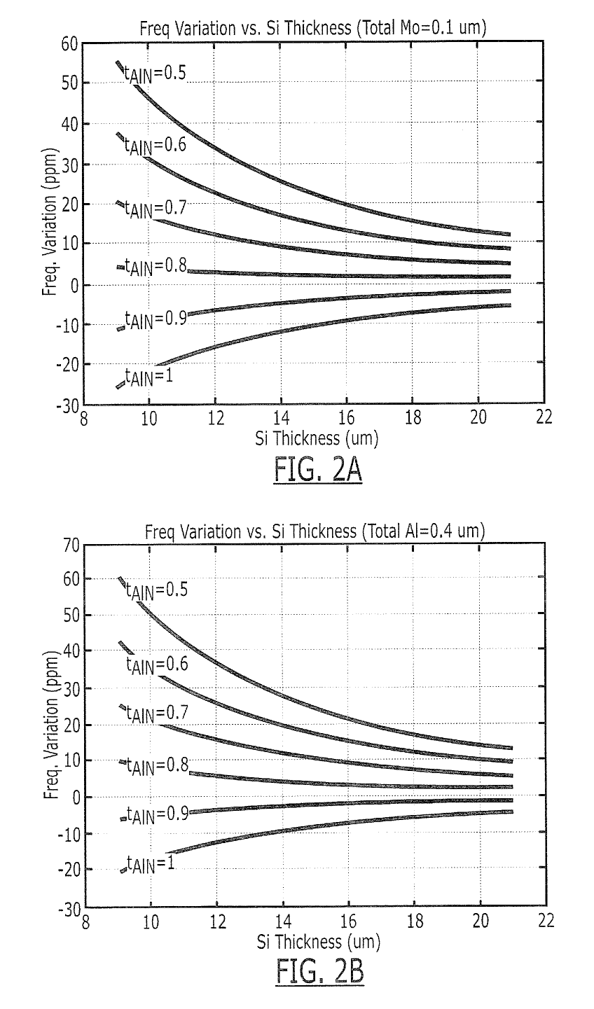

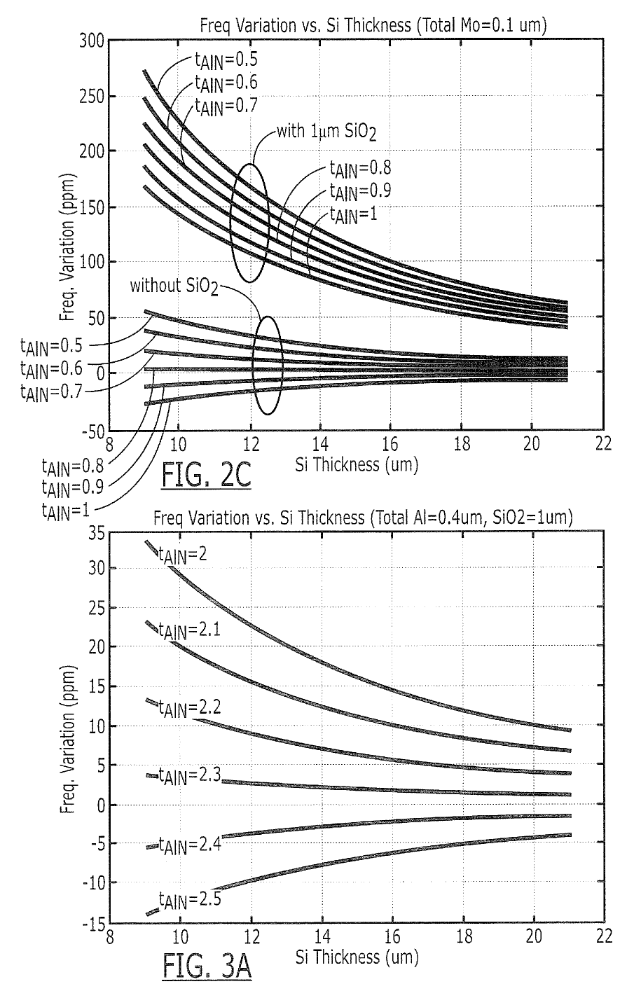

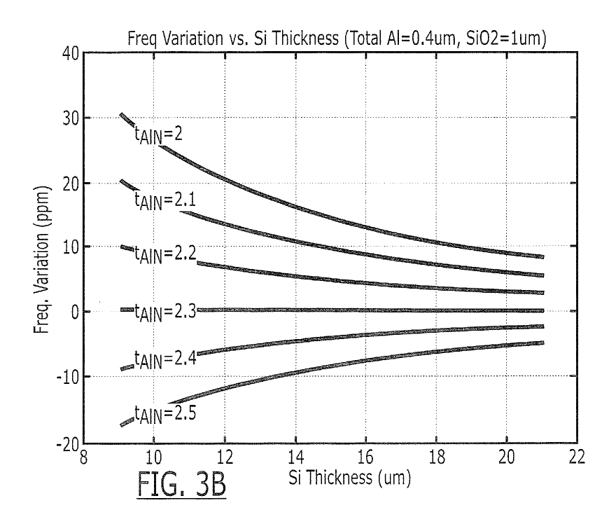

The reduction in process-induced resonant frequency variations that can be achieved by maintaining the combined thickness of the electrodes within the designated ranges can be illustrated by FIGS. 2A-2C and 3A-3B. In particular, FIG. 2A is a graph illustrating frequency variation (ppm) versus silicon resonator body thickness, for thin-film bulk acoustic resonators having aluminum nitride (AlN) piezoelectric layers of varying thickness ranging from 0.5 to 1.0 microns and molybdenum (Mo) electrodes with a combined thickness of 0.1 microns. As illustrated, a t₃/t₂ ratio of 0.12 (Mo=0.1/AlN=0.83) yields a low level of process-induced resonant frequency variation for silicon resonator bodies having a target thickness of 20 microns. Alternatively, FIG. 2B illustrates frequency variation (ppm) versus silicon resonator body thickness, for thin-film bulk acoustic resonators having aluminum nitride (AlN) piezoelectric layers of varying thickness ranging from 0.5 to 1.0 microns and aluminum (Al) electrodes with a combined thickness of 0.4 microns. As illustrated by FIG. 2B, a t₃/t₂ ratio of 0.465 (Al=0.4/AlN=0.86) yields a low level of process-induced resonant frequency variation for silicon resonator bodies having a target thickness of 20 microns.

FIG. 2C is a graph illustrating frequency variation (ppm) versus silicon resonator body thickness, for: (i) thin-film bulk acoustic resonators having aluminum nitride (AlN) piezoelectric layers of varying thickness ranging from 0.5 to 1.0 microns and molybdenum (Mo) electrodes with a combined thickness of 0.1 microns; and (ii) thin-film bulk acoustic resonators having aluminum nitride (AlN) piezoelectric layers of varying thickness ranging from 0.5 to 1.0 microns, molybdenum (Mo) electrodes with a combined thickness of 0.1 microns and a 1.0 micron thick silicon dioxide compensation layer. As illustrated, the inclusion of a silicon dioxide compensation layer on a silicon resonator body increases the degree of process-induced resonant frequency variation relative to an otherwise equivalent device.

FIG. 3A is a graph illustrating frequency variation (ppm) versus silicon resonator body thickness, for thin-film bulk acoustic resonators having aluminum nitride (AlN) piezoelectric layers of varying thickness ranging from 2 to 2.5 microns, aluminum (Al) electrodes with a combined thickness of 0.4 microns and a 1.0 micron thick silicon dioxide compensation layer. As illustrated, a t₃/t₂ of about 0.17 (i.e., 0.4/2.3) yields a relatively low level of process-induced resonant frequency variation with the silicon resonator body has a thickness of about 20 microns. This value of 0.17 is consistent with a value predicted by a left side of equation (7) for the case where the resonator's frequency defining dimension (i.e., body length) is substantially larger than the width of the resonator body.

Similarly, FIG. 3B is a graph illustrating frequency variation (ppm) versus silicon resonator body thickness, for thin-film bulk acoustic resonators having aluminum nitride (AlN) piezoelectric layers of varying thickness ranging from 2 to 2.5 microns, molybdenum (Mo) electrodes with a combined thickness of 0.1 microns and a 1.0 micron thick silicon dioxide compensation layer. As illustrated, a t₃/t₂ of about 0.043 (i.e., 0.1/2.3) yields a relatively low level of process-induced resonant frequency variation with the silicon resonator body has a thickness of about 20 microns. This value of 0.043 is consistent with a value predicted by a left side of equation (7) for the case where the resonator's frequency defining dimension (i.e., body length) is substantially larger than the width of the resonator body.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A thin-film bulk acoustic resonator, comprising:
a resonator body;
a bottom electrode on said resonator body;
a piezoelectric layer on said bottom electrode; and
a top electrode on said piezoelectric layer, said top and bottom electrodes having a combined thickness of t₃ within the following range:
$${t}_{2} [ \frac{{E}_{2} {ρ}_{1} - {E}_{1} {ρ}_{2}}{{E}_{1} {ρ}_{3} - {E}_{3} {ρ}_{1}} ] \leq {t}_{3} \leq 2 {t}_{2} [ \frac{{E}_{2} {ρ}_{1} - {E}_{1} {ρ}_{2}}{{E}_{1} {ρ}_{3} - {E}_{3} {ρ}_{1}} ] ,$$
where t₂ is the thickness of said piezoelectric layer; E₁, E₂ and E₃ are the Young's modulus of said resonator body, said piezoelectric layer and said bottom and top electrodes, respectively; and p₁, p₂ and p₃ are the densities of said resonator body, said piezoelectric layer and said bottom and top electrodes, respectively.

2. The resonator of claim 1, wherein said bottom and top electrodes comprise an electrically conductive material selected from a group consisting of molybdenum (Mo) and aluminum (Al).

3. The resonator of claim 1, wherein said piezoelectric layer comprises aluminum nitride (AlN).

4. The resonator of claim 1, further comprising an electrically insulating compensation layer on top or bottom of said resonator body.

5. The resonator of claim 4, wherein said compensation layer is a silicon dioxide layer.

6. The resonator of claim 4, further comprising an adhesion layer between said compensation layer and said bottom electrode.

7. The resonator of claim 6, wherein said adhesion layer comprises the same material as said piezoelectric layer.

8. The resonator of claim 6, wherein said adhesion layer comprises the same material as said piezoelectric layer; and wherein t₂ is a combined thickness of said piezoelectric layer and said adhesion layer.

9. The resonator of claim 1, wherein said top and bottom electrodes have a combined thickness of t₃ within the following range:
$$1.6 {t}_{2} [ \frac{{E}_{2} {ρ}_{1} - {E}_{1} {ρ}_{2}}{{E}_{1} {ρ}_{3} - {E}_{3} {ρ}_{1}} ] \leq {t}_{3} \leq 2 {t}_{2} [ \frac{{E}_{2} {ρ}_{1} - {E}_{1} {ρ}_{2}}{{E}_{1} {ρ}_{3} - {E}_{3} {ρ}_{1}} ] .$$

10. A thin-film bulk acoustic resonator, comprising:
a resonator body;
a compensation layer on top or bottom of said resonator body;
a bottom electrode on said resonator body;
a piezoelectric layer on said bottom electrode; and
a top electrode on said piezoelectric layer, said top and bottom electrodes having a combined thickness of t₃ within the following range:
$$[ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ] \leq {t}_{3} \leq 2 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ]$$
where t₂ and t₄ are the thicknesses of said piezoelectric layer and said compensation layer, respectively; E₁, E₂, E₃ and E₄ are the Young's modulus of said resonator body, said piezoelectric layer, said bottom and top electrodes and said compensation layer, respectively; and p₁, p₂, p₃ and p₄ are the densities of said resonator body, said piezoelectric layer, said bottom and top electrodes and said compensation layer, respectively.

11. The acoustic resonator of claim 10, wherein said compensation layer is an electrically insulating dielectric layer.

12. The resonator of claim 10, wherein said bottom and top electrodes comprise an electrically conductive material selected from a group consisting of molybdenum (Mo) and aluminum (Al).

13. The resonator of claim 10, wherein said piezoelectric layer comprises aluminum nitride (AlN).

14. The resonator of claim 10, further comprising an adhesion layer between said compensation layer and said bottom electrode.

15. The resonator of claim 14, wherein said adhesion layer comprises the same material as said piezoelectric layer; and wherein t₂ is a combined thickness of said piezoelectric layer and said adhesion layer.

16. The resonator of claim 15, wherein said top and bottom electrodes have a combined thickness of t₃ within the following range:
$$1.6 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ] \leq {t}_{3} \leq 2 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ]$$

17. The resonator of claim 10, wherein said top and bottom electrodes have a combined thickness of t₃ within the following range:
$$1.6 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ] \leq {t}_{3} \leq 2 [ \frac{\frac{{ρ}_{2}}{{ρ}_{1}} {t}_{2} + \frac{{ρ}_{4}}{{ρ}_{1}} {t}_{4} - \frac{{E}_{2}}{{E}_{1}} {t}_{2} - \frac{{E}_{4}}{{E}_{1}} {t}_{4}}{\frac{{E}_{3}}{{E}_{1}} - \frac{{ρ}_{3}}{{ρ}_{1}}} ]$$

18. A thin-film bulk acoustic resonator, comprising:
a resonator body;
a bottom electrode comprising molybdenum, on said resonator body;
a piezoelectric layer on said bottom electrode; and
a top electrode comprising molybdenum on said piezoelectric layer, said top and bottom electrodes having a combined thickness in a range from greater than about 0.12 to about 0.24 times a thickness of said piezoelectric layer.

19. The resonator of claim 18, further comprising a piezoelectric adhesion layer on said resonator body.

20. The resonator of claim 19, further comprising a compensation layer on top or bottom of said resonator body.

21. The resonator of claim 20, wherein said compensation layer comprises silicon dioxide.

22. A thin-film bulk acoustic resonator, comprising:
a resonator body;
a bottom electrode comprising aluminum, on said resonator body;
a piezoelectric layer on said bottom electrode; and
a top electrode comprising aluminum on said piezoelectric layer, said top and bottom electrodes having a combined thickness in a range from greater than about 0.46 to about 0.93 a thickness of said piezoelectric layer.

23. The resonator of claim 22, further comprising a piezoelectric adhesion layer extending between said bottom electrode and said resonator body.

24. The resonator of claim 23, further comprising a compensation layer on top or bottom of said resonator body.

25. The resonator of claim 24, wherein said compensation layer comprises silicon dioxide.
